(19) United States
(12) Patent Application Publication
(10) Pub. No.: US 2024/0096806 A1
(43) Pub. Date: Mar. 21, 2024

(54) SEMICONDUCTOR STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: CHAO-HSUAN CHEN, HSIN-CHU (TW); WEI CHEN HUNG, HSINCHU CITY (TW); LI-WEI YIN, HSINCHU CITY (TW); YU-HSIEN LIN, KAOHSIUNG CITY (TW); YIH-ANN LIN, HSINCHU (TW); RYAN CHIA-JEN CHEN, HSINCHU (TW)

(21) Appl. No.: 18/150,809

(22) Filed: Jan. 6, 2023

Related U.S. Application Data
(60) Provisional application No. 63/376,458, filed on Sep. 21, 2022.

(51) Int. Cl. H01L 23/535; H01L 21/28; H01L 21/768; H01L 29/08; H01L 29/49; H01L 29/66; H01L 29/78

(52) U.S. Cl. CPC H01L 23/535; H01L 21/28088; H01L 21/76805; H01L 21/76895; H01L 29/0847; H01L 29/4966; H01L 29/66545; H01L 29/66795; H01L 29/7851

(57) ABSTRACT

A method for manufacturing a semiconductor structure is provided. A substrate including a fin structure is received, provided or formed. A sacrificial gate layer is formed over the fin structure and a source/drain structure is formed adjacent to the sacrificial gate layer, wherein the sacrificial gate layer is surrounded by a dielectric structure. The sacrificial gate layer is removed, wherein a recess is defined by the dielectric structure. A work function layer is formed in the recess, wherein the work function layer includes an overhang portion at an opening of the recess. A thickness of the work function layer is reduced. A glue layer is formed over the work function layer. A semiconductor structure thereof is also provided.

### PRIORITY CLAIM AND CROSS-REFERENCE

This application claims the benefit of prior-filed provisional application No. 63/376,458, filed on 21 Sep. 2022.

### BACKGROUND

Semiconductor devices are used in a variety of electronic applications, such as personal computers, cellular phones, digital cameras, and other electronic equipment. The semiconductor devices are typically fabricated by sequentially depositing insulating or dielectric layers, conductive layers, and semiconductive layers of material over a semiconductor substrate, and patterning the various material layers using lithography to form circuit components and elements thereon. As the semiconductor industry has progressed into advanced technology process nodes in pursuit of greater device density, issues of over-etching effect and damage to a channel region of a transistor have arisen.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a flow diagram of a method for manufacturing a semiconductor structure in accordance with some embodiments of the present disclosure.

FIG. 2 is a flow diagram of a method for manufacturing a semiconductor structure in accordance with some embodiments of the present disclosure.

FIGS. 3A, 7A, 11A, 14A, and 16A are schematic three-dimensional (3D) diagrams of a semiconductor structure including a short-channel region at different stages of the method in accordance with some embodiments of the present disclosure.

FIGS. 3B, 7B, 11B, 14B, and 16B are schematic 3D diagrams of a semiconductor structure including a long-channel region at different stages of the method in accordance with some embodiments of the present disclosure.

FIGS. 4A, 5A, 6A, 8A, 9A, 10A, 12A, 13A, 15A, 17A and 18A are schematic cross-sectional diagrams of a semiconductor structure along a line A-A′ in FIG. 3A at different stages of the method in accordance with some embodiments of the present disclosure.

FIGS. 4B, 5B, 6B, 8B, 9B, 10B, 12B, 13B, 15B, 17B and 18B are schematic cross-sectional diagrams of a semiconductor structure along a line B-B′ in FIG. 3B at different stages of the method in accordance with some embodiments of the present disclosure.

FIG. 11C is a schematic cross-sectional diagram of a semiconductor structure along a line C-C′ in FIG. 11B at a stage of the method in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of times, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

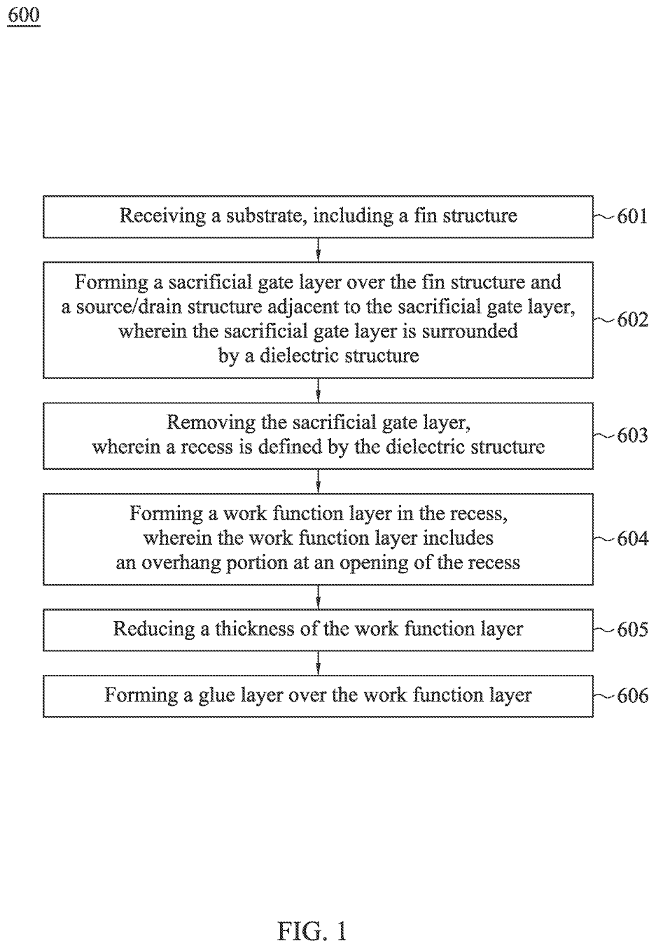

FIG. 1 is a flow diagram of a method 600 for manufacturing a semiconductor structure in accordance with some embodiments of the present disclosure. The method 600 includes a number of operations (601, 602, 603, 604, 605 and 606) and the description and illustration are not deemed as a limitation to the sequence of the operations. In the operation 601, a substrate including a fin structure is received, provided or formed. In the operation 602, a sacrificial gate layer is formed over the fin structure and a source/drain structure is formed adjacent to the sacrificial gate layer, wherein the sacrificial gate layer is surrounded by a dielectric structure. In the operation 603, the sacrificial gate layer is removed, wherein a recess is defined by the dielectric structure. In the operation 604, a work function layer is formed in the recess, wherein the work function layer includes an overhang portion at an opening of the recess. In the operation 605, a thickness of the work function layer is reduced. In the operation 606, a glue layer is formed over the work function layer. It should be noted that the operations of the method 600 may be rearranged or otherwise modified within the scope of the various aspects. Additional processes may be provided before, during, and after the method 600, and some other processes may be only briefly described herein. Thus, other implementations are possible within the scope of the various aspects described herein.

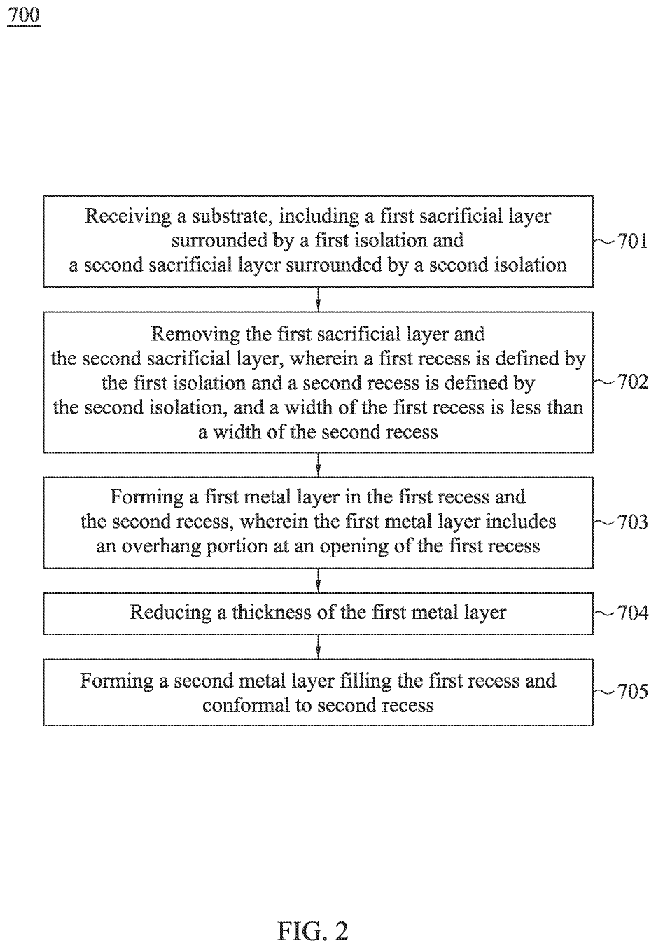

FIG. 2 is a flow diagram of a method 700 for manufacturing a semiconductor structure in accordance with some embodiments of the present disclosure. The method 700 includes a number of operations (701, 702, 703, 704 and 705) and the description and illustration are not deemed as a limitation to the sequence of the operations. In the operation 701, a substrate, including a first sacrificial layer surrounded by a first isolation and a second sacrificial layer surrounded by a second isolation, is received, provided or formed. In the operation 702, the first sacrificial layer and the second sacrificial layer are removed, wherein a first recess is defined by the first isolation and a second recess is defined by the second isolation, and a width of the first recess is less than a width of the second recess. In the operation 703, a first metal layer is formed in the first recess and the second recess, wherein the first metal layer includes an overhang portion at an opening of the first recess. In the operation 704, a thickness of the first metal layer is reduced. In the operation 705, a second metal layer filling the first recess and conformal to the second recess is formed. It should be noted that the operations of the method 700 may be rearranged or otherwise modified within the scope of the various aspects. Additional processes may be provided before, during, and after the method 700, and some other processes may be only briefly described herein. Thus, other implementations are possible within the scope of the various aspects described herein.

The method 600 and the method 700 are within the same concept of the present disclosure, and in order to further illustrate details of the method 600, the method 700, and the concept of the present disclosure, the method 600 and the method 700 are comprehensively illustrated with embodiments of the present disclosure.

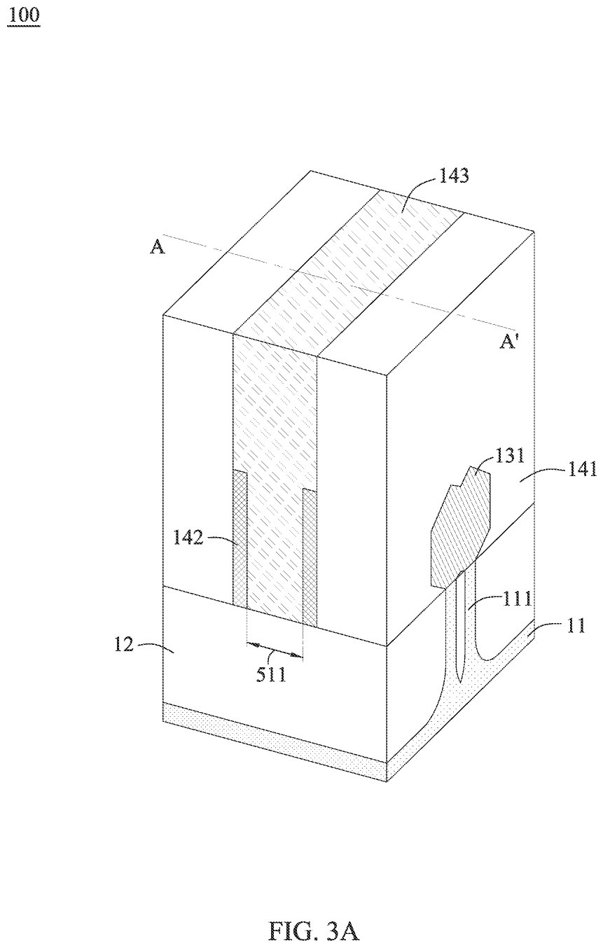

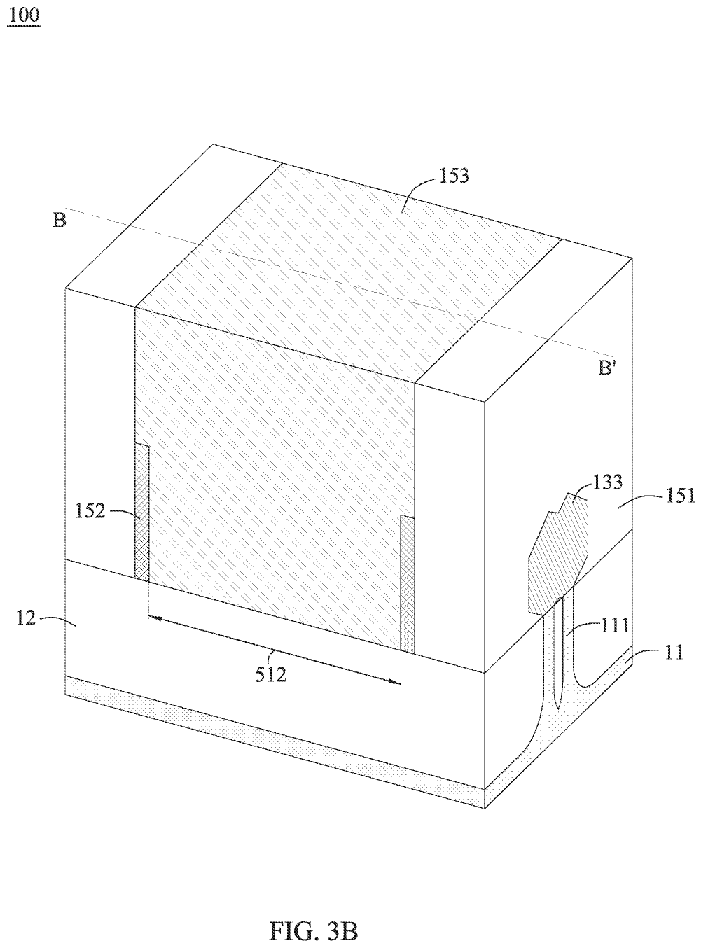

FIGS. 3A, 3B, 4A, 4B, 5A, 5B, 6A, 6B, 7A, 7B, 8A, 8B, 9A, 9B, 10A, 10B, 11A, 11B, 11C, 12A, 12B, 13A, 13B, 14A, 14B, 15A, 15B, 16A, 16B, 17A, 17B, 18A and 18B are schematic diagrams of a semiconductor structure at different stages of the method 600 and/or the method 700 in accordance with some embodiments of the present disclosure, wherein the figures with numerals followed by an “A” are schematic diagrams of intermediate structures during formation of a transistor including a short channel, and the figures with numerals followed by a “B” are schematic diagrams of intermediate structures during formation of a transistor including a long channel.

FIGS. 3A and 3B are schematic three-dimensional (3D) diagrams of different portions of an incoming substrate 100 at a stage of the method 600 and/or the method 700 in accordance with some embodiments of the present disclosure. In the operations 601 and 602 of the method 600 and/or the operation 701 of the method 700, the substrate 100 is formed, received or provided. In some embodiments, the substrate 100 includes a semiconductor layer 11 and a plurality of fin structures 111 formed thereon.

In some embodiments, the semiconductor layer 11 includes a bulk semiconductor material, such as silicon (single crystalline silicon or polycrystalline silicon). In some embodiments, the semiconductor layer 11 is a raw wafer. In some embodiments, the semiconductor layer 11 includes other semiconductor materials, such as silicon germanium, silicon carbide, gallium arsenide, or the like. In some embodiments, portions of the semiconductor layer 11 are removed, thereby forming the plurality of fin structures 111. In some embodiments, the substrate 100 includes a dielectric layer 12 over the semiconductor layer 11 and between the fin structures 111.

In order to form transistors with different channel lengths, sacrificial gate layers 143 and 153 having different widths are formed over the fin structures 111. In some embodiments, each of the sacrificial gate layers 143 and 153 extends across the fin structures 111. In some embodiments, an extending direction of each of the sacrificial gate layers 143 and 153 is substantially perpendicular to an extending direction of the fin structures 111. The sacrificial gate layers 143 and 153 may include same or different materials. In some embodiments, the sacrificial gate layers 143 and 153 are formed concurrently by a deposition of polysilicon. In some embodiments, each of the sacrificial gate layers 143 and 153 is a multi-layer structure (e.g., a hard sub-layer over a polysilicon sub-layer). Details of the sacrificial gate layers 143 and 153 are omitted from the figures for a purpose of illustration, and such omission is not intended to limit the present disclosure. In some embodiments, a width 511 of the sacrificial gate layer 143 proximal to the fin structure 111 is less than a width 512 of the sacrificial gate layer 153 proximal to the fin structure 111. The width 511 can define a first channel length of a first transistor to be formed, and the width 512 can define a second channel length of a second transistor to be formed. The widths 511 and 512 of the sacrificial gate layers 143 and 153 may be defined by spacers 142 and 152 respectively. In some embodiments, the width 511 is in a range of 20 to 100 nanometers (nm). In some embodiments, the width 512 is in a range of 100 to 250 nm. In some embodiments, a pair of the spacers 142 are disposed at two opposite sides of the sacrificial gate layer 143. In some embodiments, a pair of the spacers 152 are disposed at two opposite sides of the sacrificial gate layer 153. The spacers 142 and 152 may comprise same or different dielectric materials (e.g., oxide, nitride, oxynitride, low-k dielectric materials, high-k dielectric materials, or other suitable dielectric materials). In some embodiments, the spacers 142 and 152 are formed concurrently by a deposition.

The substrate 100 may include a dielectric layer 141 surrounding the sacrificial gate layer 143 and the spacers 142, and a dielectric layer 151 surrounding the sacrificial gate layer 153 and the spacers 152. The dielectric layers 141 and 151 may include same or different dielectric materials. In some embodiments, the dielectric layers 141 and 151 are formed concurrently by a deposition. In some embodiments, the dielectric layers 141 and 151 are formed after formation of the spacers 142 and 152 and prior to formation of the sacrificial gate layers 143 and 153. In some embodiments, the dielectric layer 141 or 151 is referred to as an isolation.

In some embodiments, a top surface of the dielectric layer 141 is higher than a top surface of the spacer 142, and a portion of the sacrificial gate layer 143 covers the top surface of the spacer 142. In some embodiments, the top surface of the sacrificial gate layer 143 is substantially aligned or coplanar with the top surface of the dielectric layer 141. Similarly, in some embodiments, a top surface of the dielectric layer 151 is higher than a top surface of the spacer 152, and a portion of the sacrificial gate layer 153 covers the top surface of the spacer 152. In some embodiments, the top surface of the sacrificial gate layer 153 is substantially aligned or coplanar with the top surface of the dielectric layer 151. In some embodiments, a thickness of each of the spacers 142 is substantially equal to a thickness of each of the spacers 152.

The substrate 100 may further include a plurality of source/drain structures 131 and 133. In some embodiments, the source/drain structures 131 are disposed at two opposite sides of the sacrificial gate layer 143 and are covered by the dielectric layer 141. In some embodiments, the source/drain structures 133 are disposed at two opposite sides of the sacrificial gate layer 153 and are covered by the dielectric layer 151. In some embodiments, the source/drain structures 131 and 133 are formed by an epitaxial growth. In some embodiments, the source/drain structures 131 and 133 are formed prior to the formation of the dielectric layers 141 and 142 and after the formation of the spacers 142 and 152 and the sacrificial gate layers 143 and 153. A conventional method for forming a sacrificial gate structure over a fin structure can be applied, and detailed description of formation of the substrate 100 is omitted herein.

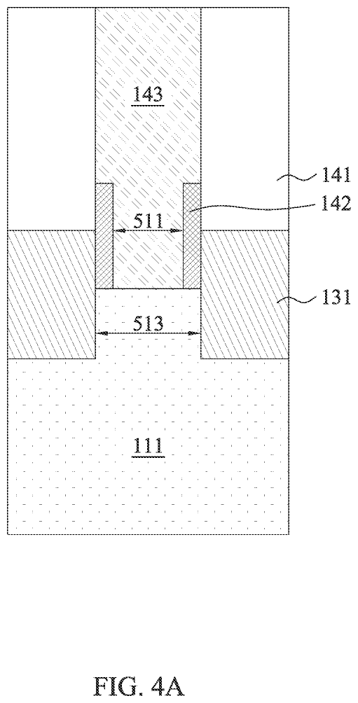

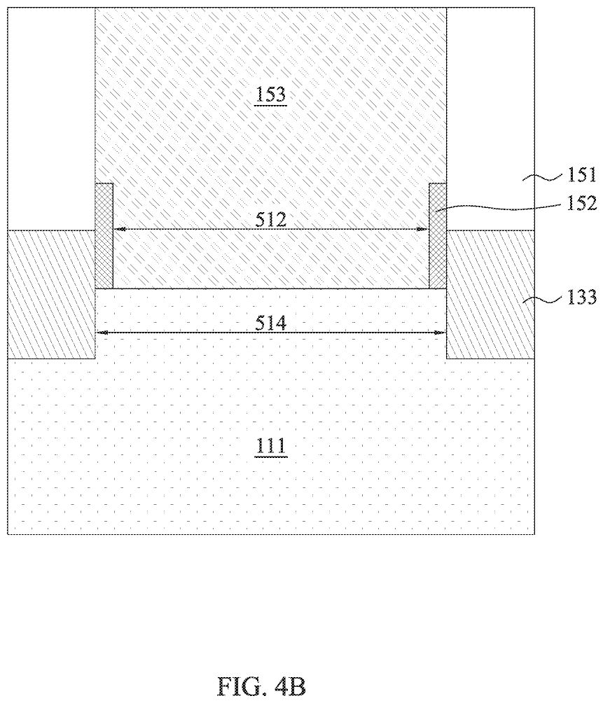

FIGS. 4A and 4B are schematic cross-sectional diagrams at a stage of the method 600 and/or the method 700 in accordance with some embodiments of the present disclosure, wherein FIG. 4A is a cross section along a line A-A′ cutting the fin structure 111 in FIG. 3A, and FIG. 4B is a cross section along a line B-B′ cutting the fin structure 111 in FIG. 3B. It should be noted that the fin structures 111 shown in FIGS. 4A and 4B can be the same fin structure 111 or different fin structures 111, and are not limited herein. In some embodiments, the substrate 100 includes an etch stop layer or a mask layer disposed between the sacrificial gate layer 143 and the fin structure 111 (not shown in the figures). Similarly, the substrate 100 may also include an etch stop layer or a mask layer disposed between the sacrificial gate layer 153 and the fin structure 111 (not shown in the figures). A distance 513 between the source/drain structures 131 defines the first channel length of the first transistor, and a distance 514 between the source/drain structures 133 defines the second channel length of the second transistor. Therefore, the distance 513 between the source/drain structures 131 can be less than the distance 514 between the source/drain structures 133.

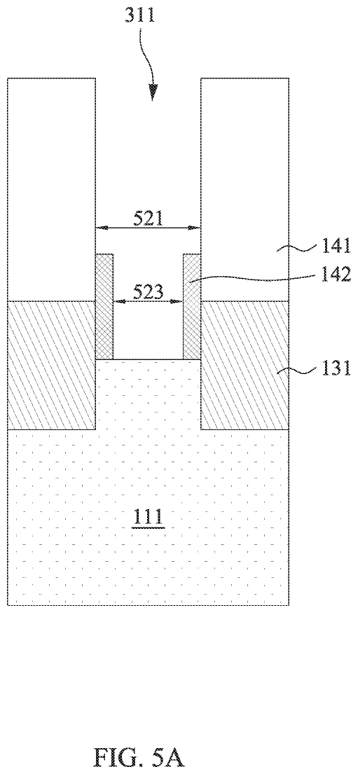

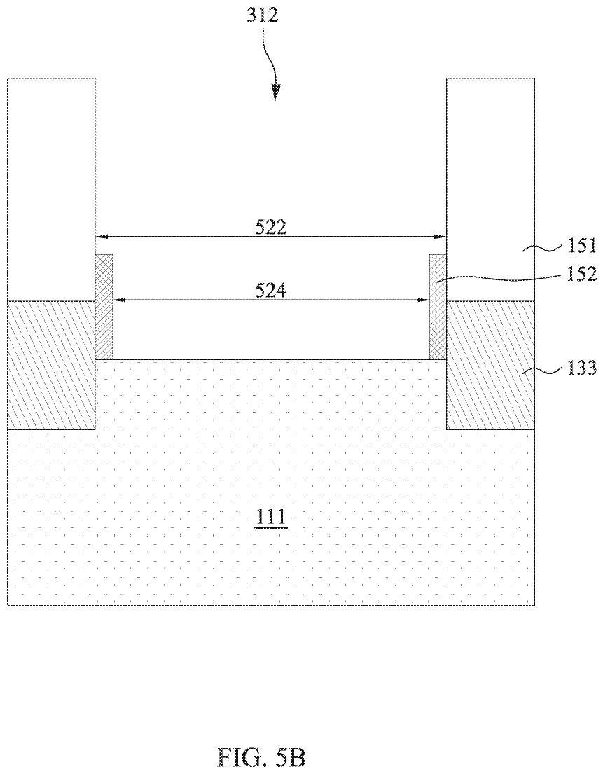

FIGS. 5A and 5B are schematic cross-sectional diagrams at a stage of the method 600 and/or the method 700 in accordance with some embodiments of the present disclosure. In the operation 603 and the operation 702, the sacrificial gate layers 143 and 153 are removed, and recesses 311 and 312 are thereby formed respectively. In some embodiments, the recess 311 is defined by the fin structure 111, the spacers 142 and the dielectric layer 141. In some embodiments, the recess 312 is defined by the fin structure 111, the spacers 152 and the dielectric layer 151. In some embodiments, a width 523 of a lower portion of the recess 311 defined by the spacers 142 is substantially less than a width 521 of an upper portion of the recess 311 defined by the dielectric layer 141. In some embodiments, a width 524 of a lower portion of the recess 312 defined by the spacers 152 is substantially less than a width 522 of an upper portion of the recess 312 defined by the dielectric layer 151.

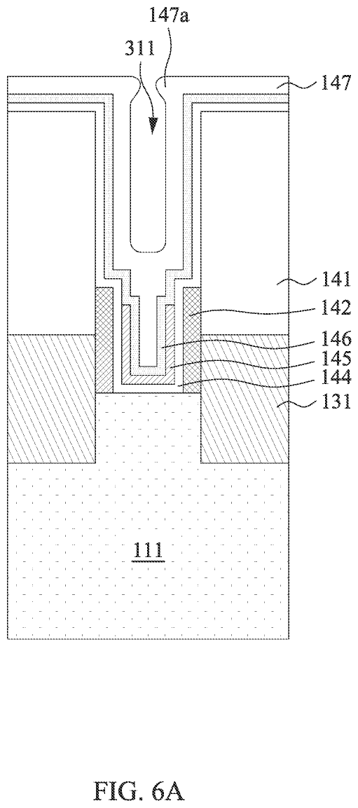

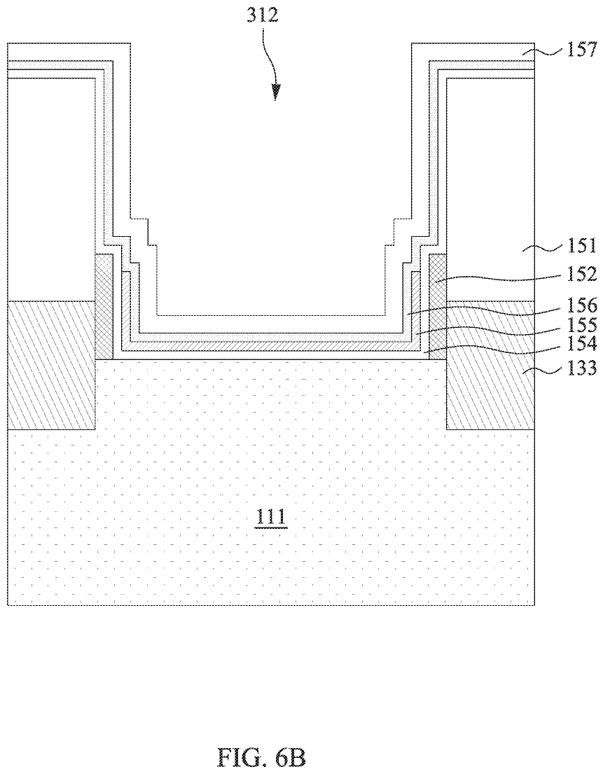

FIGS. 6A and 6B are schematic cross-sectional diagrams at a stage of the method 600 and/or the method 700 in accordance with some embodiments of the present disclosure. Prior to the operation 604 and/or the operation 703, the method 600 and/or the method 700 may include formation of high-k dielectric layers 144 and 154, first work function layers 145 and 155, and second work function layers 146 and 156 prior to formation of metal layers 147 and 157 in the operation 604 and/or operation 703. In some embodiments, the high-k dielectric layers 144 and 154 are connected. In some embodiments, the high-k dielectric layers 144 and 154 are formed concurrently by a conformal deposition. In some embodiments, the high-k dielectric layers 144 and 154 include hafnium oxide (HfOₓ), zirconium oxide (ZrO₂), lanthanum oxide-yttrium oxide (Y₂O₃), aluminum oxide (Al₂O₃), titanium oxide (TiO₂), another applicable, high-k material, or a combination thereof. In some embodiments, a thickness of the high-k dielectric layer 144 or 154 is in a range of 10 to 25 angstroms (Å).

In some embodiments, the first work function layers 145 and 155 are connected. In some embodiments, the first work function layers 145 and 155 are formed concurrently by a conformal deposition followed by an etch-back operation. In some embodiments, a thickness of the first work function layer 145 or 155 is in a range of 5 to 50 Å. In some embodiments, the thickness of the first work function layer 145 or 155 is in a range of 10 to 20 Å. In some embodiments, a top of the first work function layer 145 is lower than a top surface of the spacer 142. In some embodiments, a top of the first work function layer 155 is lower than a top of the spacer 152. In some embodiments, the second work function layers 146 and 156 are connected. In some embodiments, the second work function layers 146 and 156 are formed concurrently by a conformal deposition. In some embodiments, a thickness of the second work function layer 146 or 156 is in a range of 20 to 35 Å.

In the operation 604 and/or the operation 703, a first metal material is formed over the substrate 100. A portion of the first metal material disposed in and above the recess 311 shown in FIG. 6A defines a metal layer 147, and a portion of the first metal material disposed in and above the recess 312 shown in FIG. 6B defines a metal layer 157. In some embodiments, the metal layer 147 and the metal layer 157 are connected. In some embodiments, the metal layer 147 and the metal layer 157 are formed concurrently by a deposition. In some embodiments, the first metal material includes titanium nitride (TiN), tantalum nitride (TaN), tungsten nitride (WN), tungsten carbide nitride (WCN), titanium aluminum alloy (TiAl), titanium aluminum nitride (TiAlN), titanium aluminum carbide (TiAlC), tantalum carbide (TaC), tantalum carbon nitride (TaCN), tantalum silicon nitride (TaSiN), another suitable material, or a combination thereof. In some embodiments, the metal layer 147 and the metal layer 157 function as work function layers. In some embodiments, the metal layer 147 and the metal layer 157 function as glue layers.

The formation of the metal layers 147 and 157 can be performed after the formation of the second work function layers 146 and 156. In some embodiments, the metal layer 147 fills the lower portion of the recess 311 due the small width 523 shown in FIG. 5A. In some embodiments, a thickness of the metal layer 147 above the lower portion of the recess 311 is substantially consistent across the substrate 100. In some embodiments, a thickness of the metal layer 157 is substantially consistent across the substrate 100. In some embodiments, the thicknesses of the metal layers 147 and 157 are substantially equal. In some embodiments, the thickness of the metal layer 147 or 157 is in a range of 40 to 120 Å. In some embodiments, the metal layer 147 includes an overhang portion 147a at an opening of the recess 311 due to a property of deposition, especially when the recess 311 has a high aspect ratio. In some embodiments, the overhang portion 147a covers sidewalls of the metal layer 147 in the recess 311. In some embodiments, the overhang portion 147a defines an opening without sealing the recess 311. In some embodiments, a profile of the metal layer 157 is conformal to a profile of the recess 312.

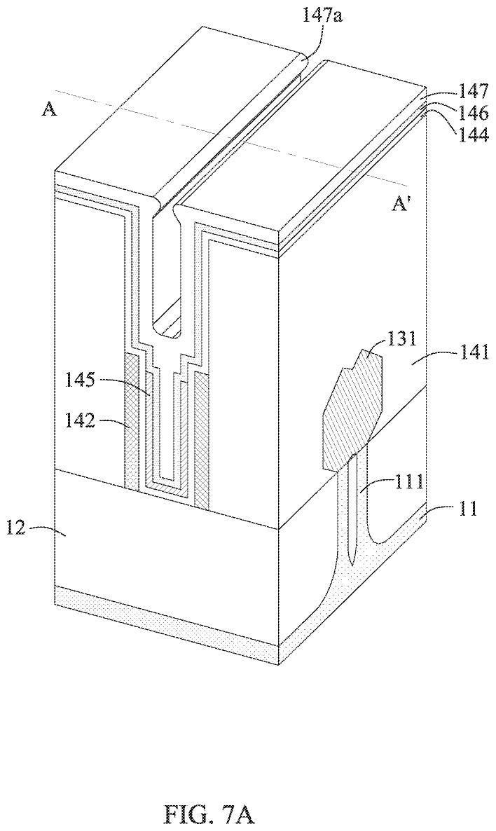

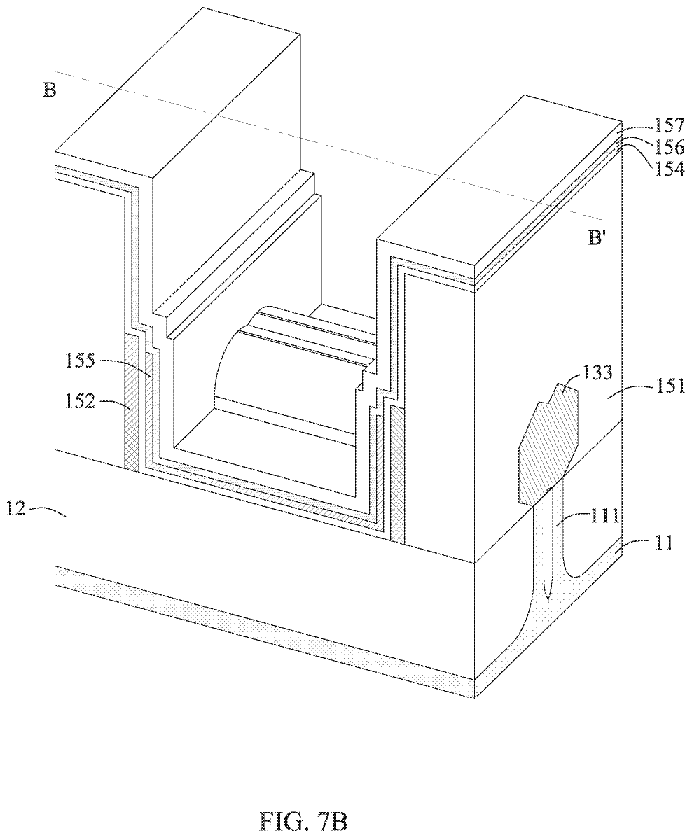

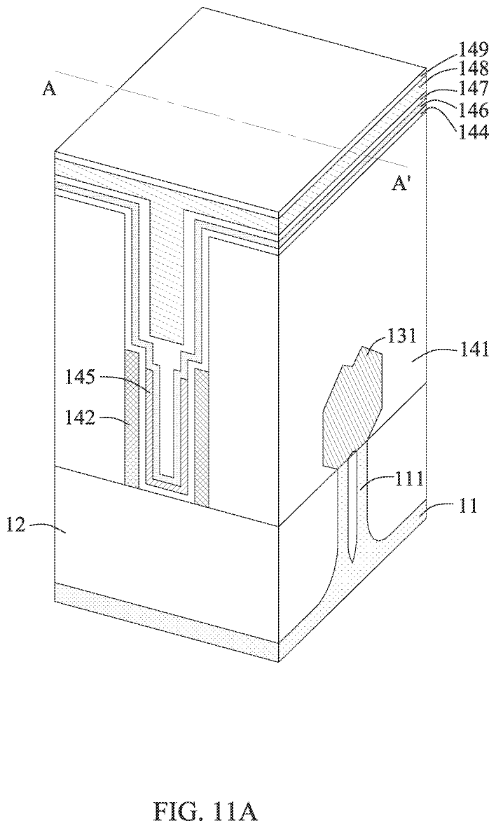

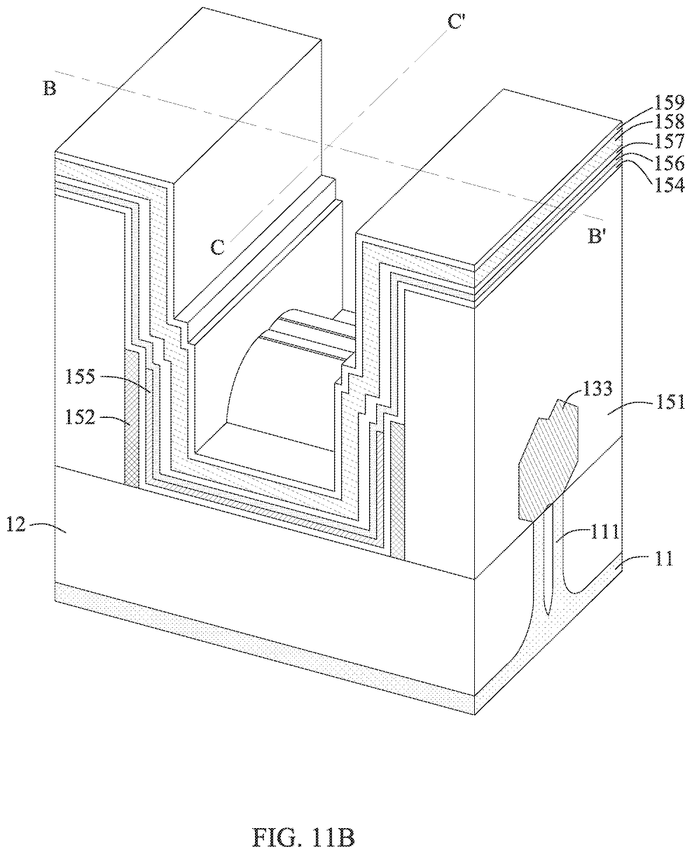

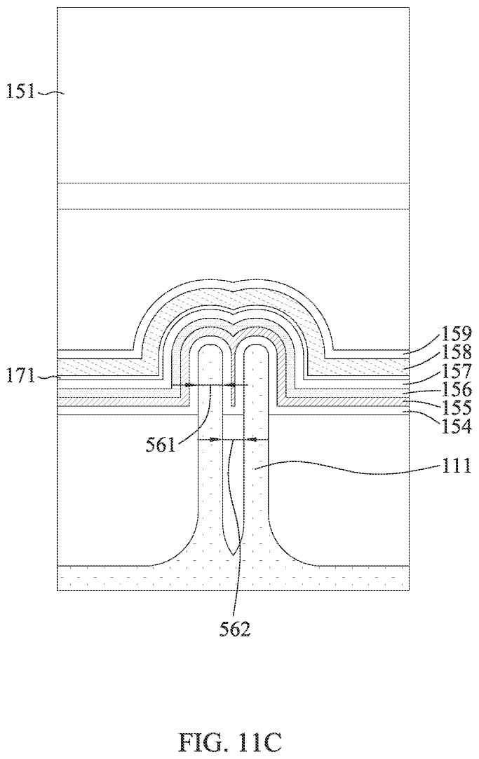

FIGS. 7A and 7B are schematic 3D diagrams of FIGS. 6A and 6B in accordance with some embodiments of the present disclosure. In some embodiments, the high-k dielectric layer 144, the first work function layer 145, and the second work function layer 146 are sequentially formed over and conformal to a profile of the fin structures 111. In some embodiments, the high-k dielectric layer 154, the first work function layer 155, and the second work function layer 156 are sequentially formed over and conformal to a profile of the fin structures 111 (as shown in FIG. 11C; a detailed description is provided below). In some embodiments, the metal layer 157 fills a gap between the fin structures 111 (as shown in FIG. 11C). In some embodiments, the metal layer 157 is conformal to a profile of the second work function layer 156.

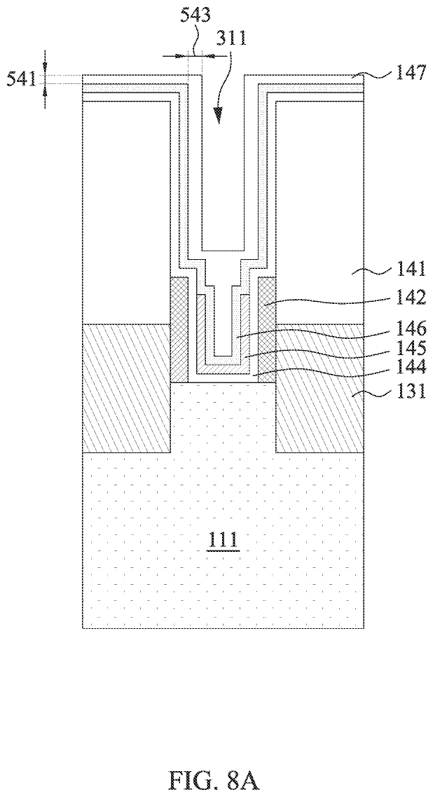

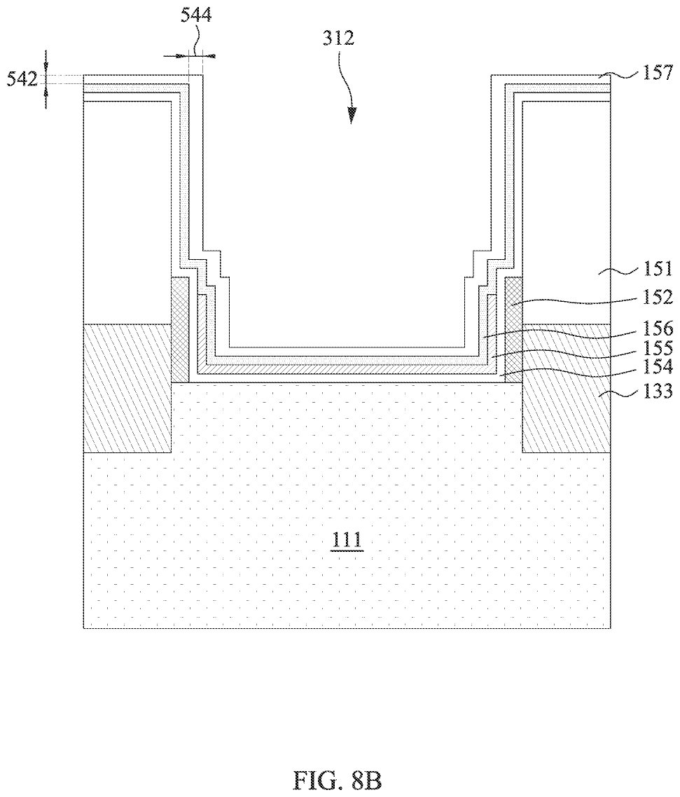

FIGS. 8A and 8B are schematic cross-sectional diagrams at a stage of the method 600 and/or the method 700 in accordance with some embodiments of the present disclosure. In the operation 605 and the operation 704, the thicknesses of the metal layers 147 and 157 are reduced. In some embodiments, a dry etching operation is performed on the metal layers 147 and 157, thereby reducing the thicknesses of the metal layers 147 and 157. The overhang portion 147a may be removed by the dry etching operation. In some embodiments, an overall thickness of the metal layers 147 and 157 is reduced by 20% to 60%. In some embodiments, the dry etching operation includes a non-directional plasma etching operation, and a removal rate of the non-directional plasma etching operation on horizontal portions of the metal layers 147 and 157 is greater than a removal rate of the non-directional plasma etching operation on vertical portions of the metal layers 147 and 157.

The dry etching operation is for a purpose of removing the overhang portion 147a in order to prevent formation of a void in a subsequent recess-filling operation. In some embodiments, the metal layers 147 and 157 are trimmed by the dry etching operation. In some embodiments, the dry etching operation can be a multi-step process. In some embodiments, the dry etching operation includes multiple etching steps for a purpose of fine-tuning shapes of the trimmed metal layers 147 and 157. In some embodiments, the dry etching operation stops after the overhang portion 147a is removed. In some embodiments, a removed amount of the metal layer 157 or an amount of reduction in thickness of the metal layer 157 corresponds to a size (or a protruding length) of the overhang portion 147a. Etching gases and process parameters of the dry etching operation can be adjusted according to a desired trimmed profile and a material of the metal layers 147 and 157. In some embodiments, the process gases include argon (Ar), chlorine (Cl), bromine (Br), hydrogen bromide (HBr), boron trichloride (BCl₃), nitrogen (N₂), nitrogen trifluoride (NF₃), carbon tetrafluoride (CF₄), methane (CH₄), oxide (O₂), or a combination thereof. Process parameters, such as a frequency of bias pulse, duty ratio of current, an air glow of each of the etching gases, and plasma power, can be adjusted according to different applications, and are not limited herein.

In some embodiments, a thickness 541 of a horizontal portion of the metal layer 147 above the recess 311 is substantially less than a thickness 543 of a vertical portion of the metal layer 147 in the recess 311. In some embodiments, a thickness 542 of a horizontal portion of the metal layer 157 above the recess 312 is substantially less than a thickness 544 of a vertical portion of the metal layer 157 in the recess 312. In some embodiments, the thickness 541 is substantially equal to the thickness 542. In some embodiments, the thickness 543 is substantially greater than the thickness 544 due to the overhang portion 147a shown in FIG. 6A reducing plasma bombardment on portions of the metal layer 147 in the recess 311. In some embodiments, the metal layer 147 filling the lower portion of the recess 311 remains after the dry etching operation.

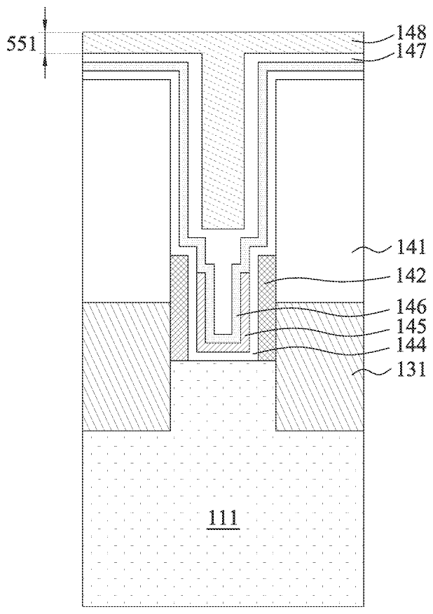

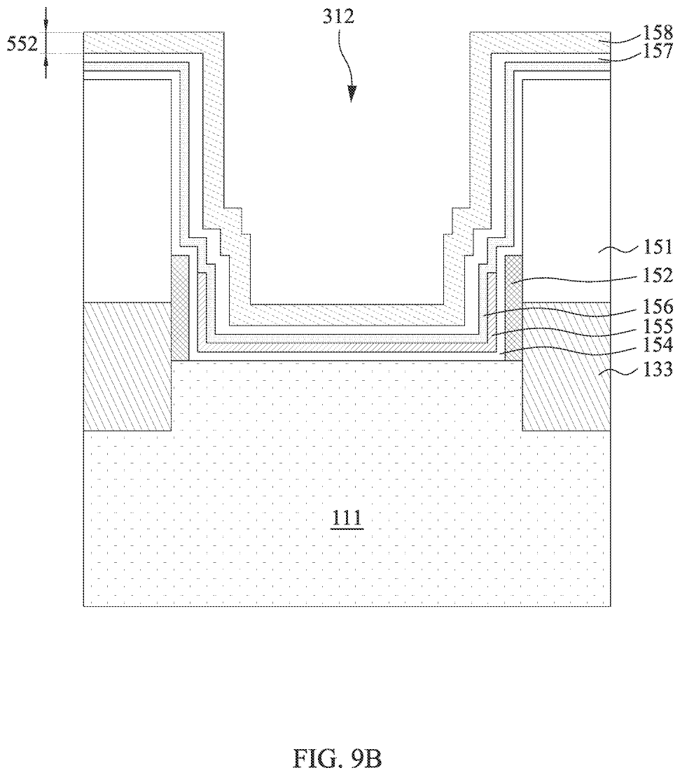

FIGS. 9A and 9B are schematic cross-sectional diagrams at a stage of the method 600 and/or the method 700 in accordance with some embodiments of the present disclosure. In the operation 606 and the operation 705, a second metal material is disposed over the substrate 100. A portion of the second metal material disposed in and above the recess 311 shown in FIG. 9A defines a metal layer 148, and a portion of the second metal material disposed in and above the recess 312 shown in FIG. 9B defines a metal layer 158. In some embodiments, the metal layer 148 and the metal layer 158 are connected. In some embodiments, the metal layer 148 and the metal layer 158 are formed concurrently by a deposition. In some embodiments, the second metal material is a metallic material selected from the options for the first metal material listed above. In some embodiments, a material of the second metal material is the same as the first metal material. In some embodiments, the second metal material includes TiN.

The metal layer 148 can fill the recess 311 or a gap defined by the metal layer 147 in the recess 311 without formation of a void as an advantage of the removal of the overhang portion 147a shown in FIG. 6A. In some embodiments, the metal layer 148 fills the recess 311 and covers the metal layer 147 outside the recess 311. In some embodiments, the metal layer 158 is conformal to the metal layer 157 in the recess 312. In some embodiments, a thickness 551 of the metal layer 148 is substantially equal to a thickness 552 of the metal layer 158. A thickness of the second metal material (e.g., the thickness 551 or 552) can be adjusted according to an amount of reduced thickness of the vertical portion of the metal layer 157 or the thickness 544 shown in FIG. 8B. To compensate for the reduced thickness 544 of the metal layer 157, a greater thickness 552 is applied for a purpose of controlling a size of a space for formation of contact plugs. In some embodiments, the thickness 551 or 552 is in a range of 100 to 200 Å. In some embodiments, the metal layer 148 and the metal layer 158 function as work function layers. In some embodiments, the metal layer 148 and the metal layer 158 function as glue layers. In some embodiments, an oxide layer (not shown) is formed between the first metal material and the second metal material after the dry etching operation. In some embodiments, the oxide layer is a native oxide layer. In some embodiments, the oxide layer is formed by an oxidation of the metal layers 147 and 157. In some embodiments, the oxide layer is formed on an entirety of top surfaces of the metal layers 147 and 157. In some embodiments, a thickness of the oxide layer is in a range of 0.5 to 2 nm.

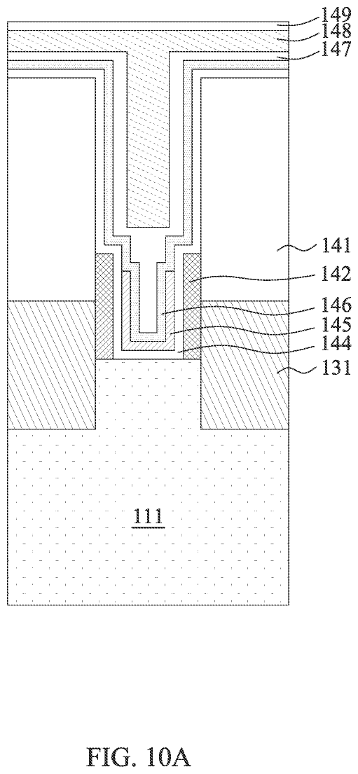

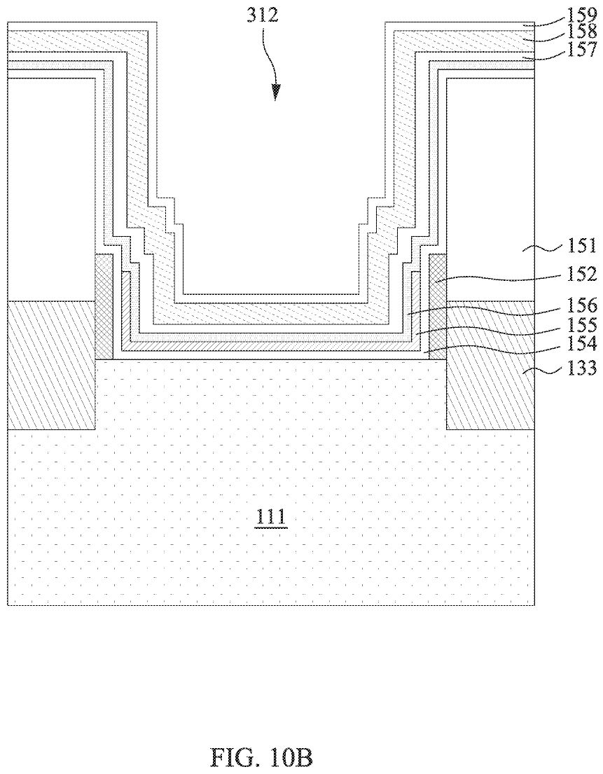

FIGS. 10A and 10B are schematic cross-sectional diagrams at a stage of the method 600 and/or the method 700 in accordance with some embodiments of the present disclosure. The method 600 and/or the method 700 may further include formation of a conductive material over the metal layers 148 and 158. The conductive material disposed over the metal layer 148 shown in FIG. 10A defines a metal layer 149, and the conductive material disposed over the metal layer 158 defines a metal layer 159. In some embodiments, the metal layer 159 is disposed in the recess 312 and conformal to the metal layer 158. In some embodiments, an entirety of the metal layer 149 is disposed above the dielectric layer 141. In some embodiments, the conductive material includes aluminum (Al), copper (Cu), tungsten (W), titanium (Ti), tantalum (Ta), or other applicable materials. In some embodiments, the metal layers 149 and 159 are formed concurrently by an atomic layer deposition (ALD). In some embodiments, a thickness of the metal layer 149 and a thickness of the metal layer 159 are substantially equal. In some embodiments, the thickness of the metal layer 149 or 159 is in a range of 7 to 12 nm.

FIGS. 11A and 11B are schematic 3D diagrams of FIGS. 10A and 10B in accordance with some embodiments of the present disclosure. FIG. 11C is a schematic cross-sectional diagram along a line C-C′ in FIG. 11B in accordance with some embodiments of the present disclosure. In some embodiments, a width 561 of the fin structure 111 is in a range of 3 to 50 nm. In some embodiments, the width 561 is in a range of 5 to 20 nm. In some embodiments, a distance 562 between adjacent fin structures 111 is in a range of 3 to 50 nm. In some embodiments, the distance 562 is in a range of 4 to 30 nm. In some embodiments, the distance 562 is substantially equal to the width 561. In some embodiments, the high-k dielectric layer 154, the first work function layer 155, and the second work function layer 156 are sequentially disposed over and conformal to the profile of the fin structures 111. The metal layer 157 may or may not fill the gap between the fin structures 111 depending on different applications. In some embodiments as shown in FIG. 11C, the metal layer 157 fills the gap between the fin structures 111. In some embodiments in which an oxide layer 171 is formed over the metal layer 157 as described above, the oxide layer 171 is conformal to the metal layer 157. In some embodiments, the metal layer 159 is conformal to the oxide layer 171 or the metal layer 157.

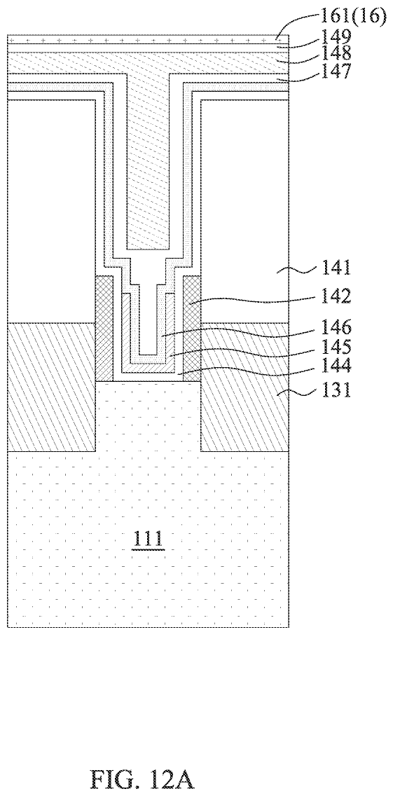

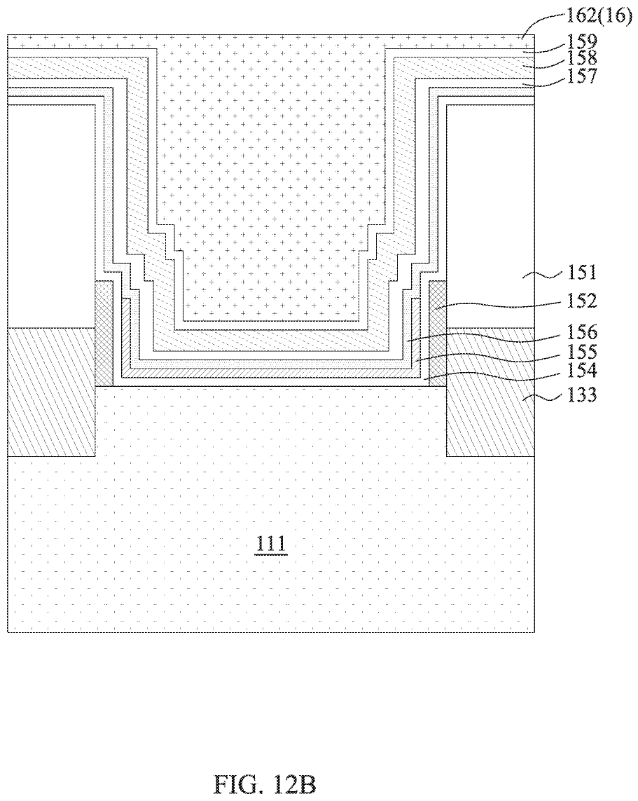

FIGS. 12A and 12B are schematic cross-sectional diagrams at a stage of the method 600 and/or the method 700 in accordance with some embodiments of the present disclosure. The method 600 and/or the method 700 may further include formation of a dielectric material 16 over the metal layers 149 and 159. In some embodiments, the dielectric material 16 includes a dielectric layer 161 disposed over the metal layer 149 and a dielectric layer 162 disposed over the metal layer 159. In some embodiments, the dielectric layer 161 is a planar portion of the dielectric material 16 disposed above the dielectric layer 141. In some embodiments, the dielectric layer 162 includes a portion filling the recess 312 and surrounded by the metal layer 159 and a planar portion disposed above the dielectric layer 151. In some embodiments, the dielectric material 16 includes nitride, such as silicon nitride. In some embodiments, the dielectric material 16 is composed of a dielectric material different from that of the dielectric layer 151 or 141.

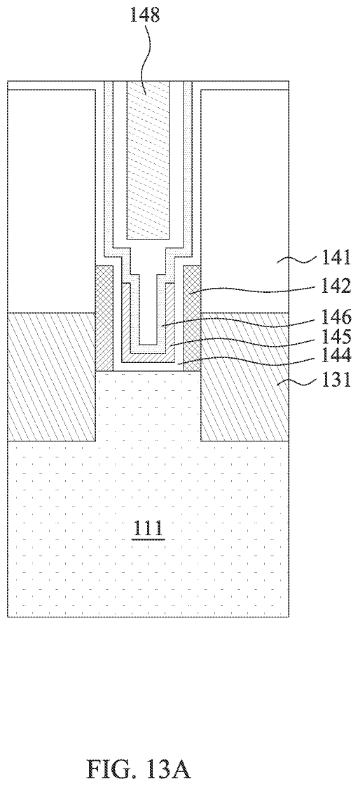

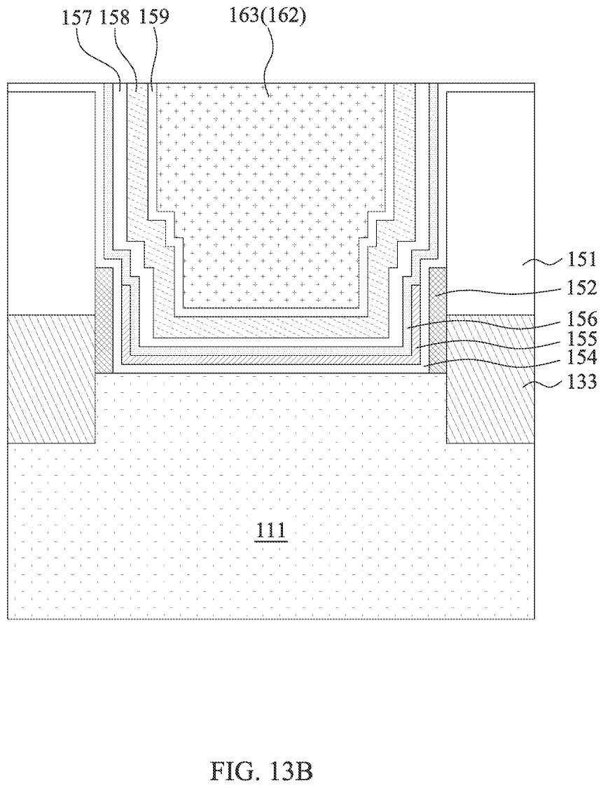

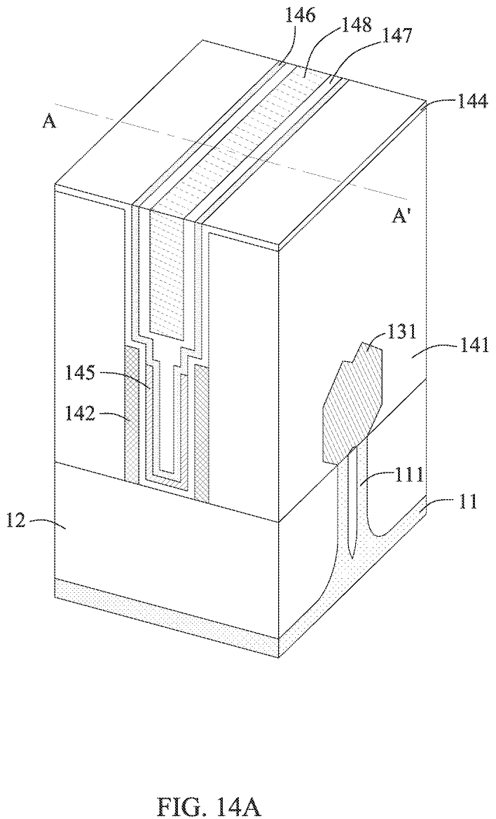

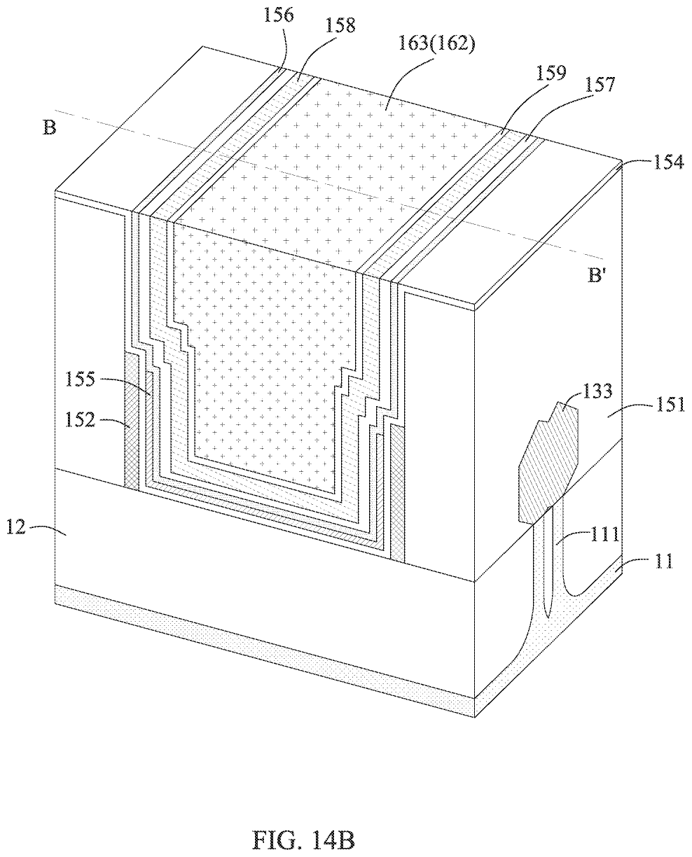

FIGS. 13A and 13B are schematic cross-sectional diagrams at a stage of the method 600 and/or the method 700 in accordance with some embodiments of the present disclosure. FIGS. 14A and 14B are schematic 3D diagrams of FIGS. 13A and 13B in accordance with some embodiments of the present disclosure. The method 600 and/or the method 700 may further include exposing the high-k dielectric layers 144 and 154 over top surfaces of the dielectric layers 141 and 151, respectively. In some embodiments, one or more etching operations are performed to remove portions of the layers 146, 147, 148 and 149, portions of the layers 156, 157, 158 and 159, and portions of the dielectric material 16 disposed above the high-k dielectric layers 144 and 154. A portion of the dielectric layer 162 surrounded by the metal layer 159 below exposed surfaces of the high-k dielectric layers 144 and 154 is left remaining and labeled 163 for a purpose of illustration. In some embodiments, a planarization is performed to remove the metal layers disposed above the high-k dielectric layers 144 and 154. In some embodiments, the planarization or the etching operation stops upon the exposure of the high-k dielectric layers 144 and 154. In some embodiments, portions of the high-k dielectric layers 144 and/or 154 above the dielectric layers 141 and/or 151 are removed due to an over-etching effect. In some embodiments, at least some of the top surfaces of the dielectric layers 141 and 151 are exposed.

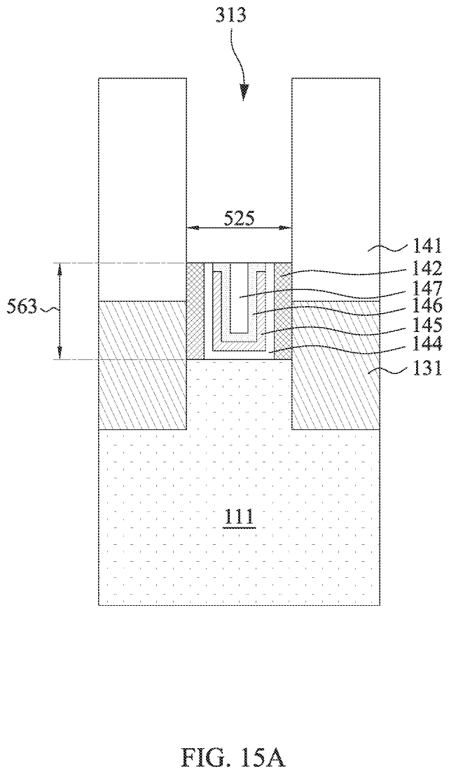

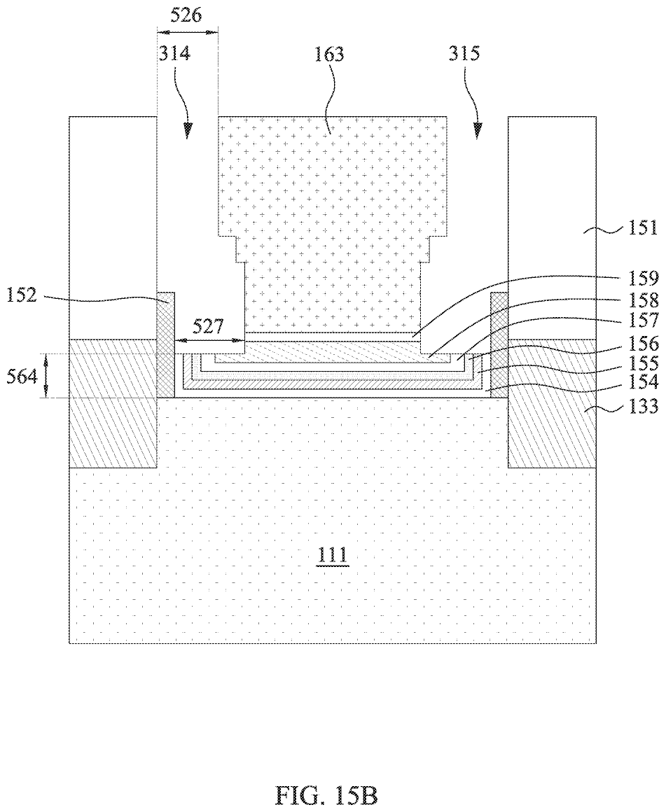

FIGS. 15A and 15B are schematic cross-sectional diagrams at a stage of the method 600 and/or the method 700 in accordance with some embodiments of the present disclosure. The method 600 and/or the method 700 may further include removal of portions of metal layers above the fin structures 111 by a distance in a range of 5 to 30 nm. In some embodiments, portions of the metal layers 146, 147 and 148, the metal layer 149, and a portion of the high-k dielectric layer 144 surrounded by the dielectric layer 141 are removed, and a recess 313 is thereby formed. In some embodiments, an entirety of the metal layer 148 is removed. In some embodiments, an entirety of the metal layer 149 is removed. In some embodiments, a distance 563 between a bottom of the recess 313 and the fin structure 111 is in a range of 5 to 30 nm. In some embodiments, the distance 563 is in a range of 5 to 15 nm. In some embodiments, a width 525 of the recess 313 (or a distance between vertical portions of the dielectric layer 141) is in a range of 8 to 50 nm. In some embodiments, the width 525 is in a range of 10 to 20 nm. The bottom of the recess 313 can be higher than, aligned with, or lower than the top of the spacers 142. In some embodiments as shown in FIG. 15A, the bottom of the recess 313 is aligned with the top of the spacers 142. Similarly, in some embodiments, portions of the metal layers 156, 157, 158 and 159 and the high-k dielectric layer 154 laterally surrounding the dielectric layer 163 are removed, and recesses 314 and 315 are thereby formed. In some embodiments, a width 526 at the opening of the recess 314 is in a range of 10 to 50 nm. In some embodiments, the width 526 is in a range of 19 to 27 nm. In some embodiments, a width 527 at a bottom of the recess 314 is substantially equal to the width 526. In some embodiments, the recesses 314 and 315 are defined between the dielectric layers 151 and 163. In some embodiments, the recesses 314 and 315 are disposed at two lateral and opposite sides of the dielectric layer 163. In some embodiments, a distance 564 between a bottom of the recess 314 or 315 and the fin structure 111 is in a range of 5 to 30 nm. In some embodiments, the distance 564 is in a range of 5 to 15 nm. In some embodiments, widths at the opening and at a bottom of the recess 315 are substantially equal to the width 526 or 527. The bottom of the recess 314 or 315 can be higher than, aligned with, or lower than the tops of the spacers 152. In some embodiments as shown in FIG. 15B, the bottoms of the recesses 314 and 315 are lower than the tops of the spacers 152.

As illustrated above, the overhang portion 147a shown in FIG. 6A is removed, and the metal layer 148 can fill the recess 311 without formation of a void. Therefore, the removal of the elements as described above can be stopped above the fin structures 111 by a range of distances, and damage to the fin structures 111 can be prevented. A product yield and product performance can thus be improved.

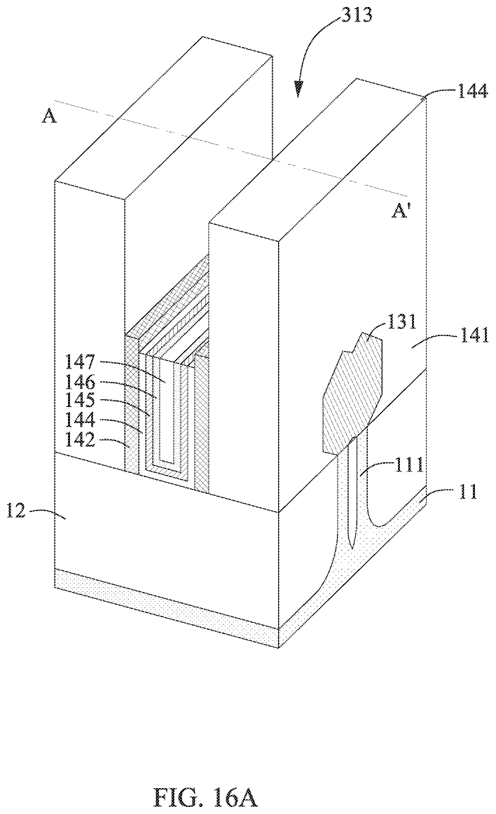

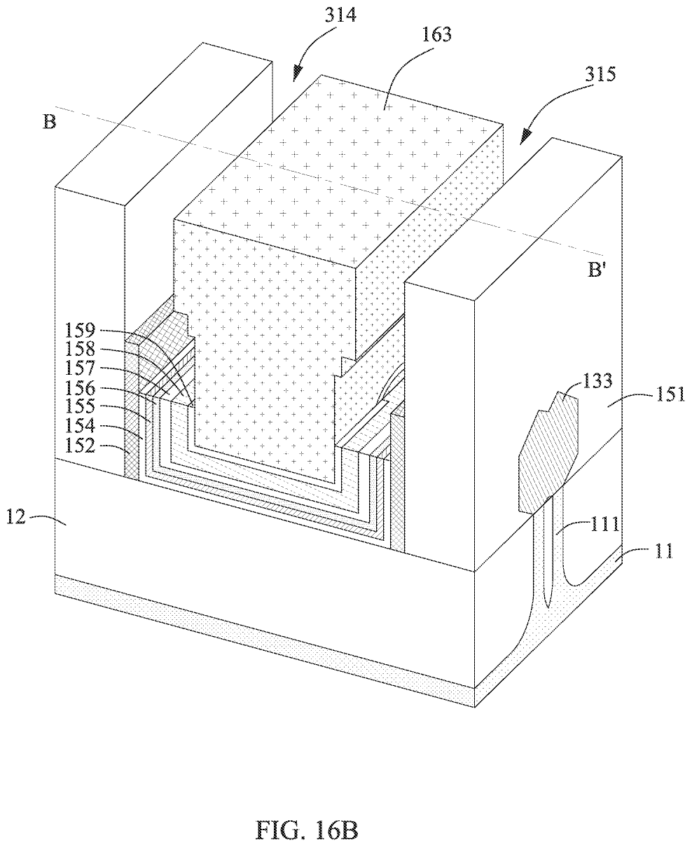

FIGS. 16A and 16B are schematic 3D diagrams at a stage of the method 600 and/or the method 700 shown in FIGS. 15A and 15B in accordance with some embodiments of the present disclosure. In some embodiments as shown in FIG. 16A, the bottom of the recess 313 is lower than the tops of the spacers 142.

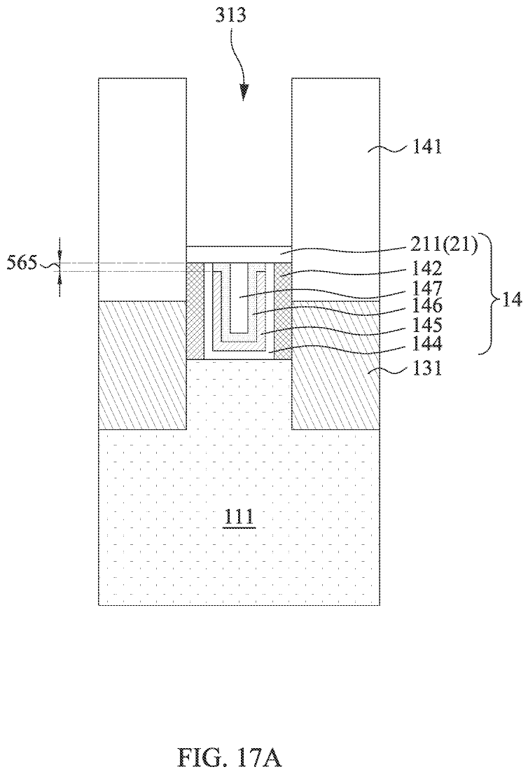

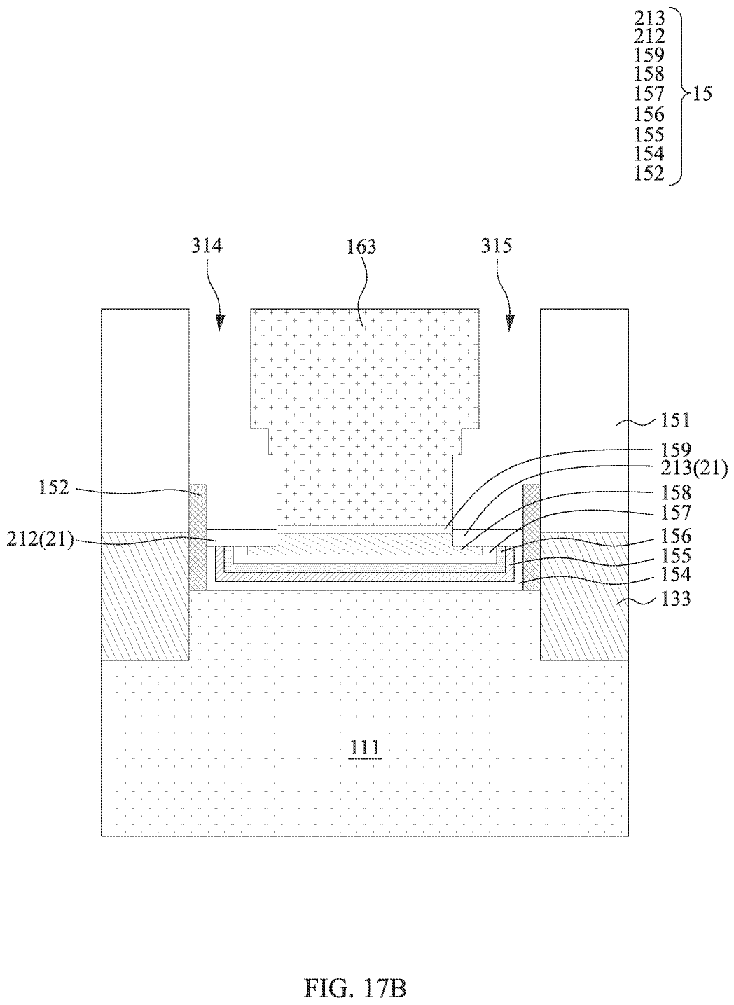

FIGS. 17A and 17B are schematic cross-sectional diagrams at a stage of the method 600 and/or the method 700 in accordance with some embodiments of the present disclosure. The method 600 and/or the method 700 may further include formation of a metallic material 21. In some embodiments, the metallic material 21 is formed by a selective deposition. In some embodiments, the metallic material 21 is formed on and grown along an exposed metal-containing surface. In some embodiments, a thickness of the metallic material 21 is in a range of 20 to 60 Å.

As shown in FIG. 17A, the metallic material 21 includes a metal layer 211 formed at a bottom of the recess 313 covering the remaining portions of the layers 144, 145, 146 and 147. In some embodiments, the metal layer 211 covers at least a portion of the tops of the spacers 142. In some embodiments, a distance 565 between the metal layer 211 and the first work function layer 145 is in a range of 0 to 10 nm. As shown in FIG. 17B, the metallic material 21 includes a metal layer 212 formed at the bottom of the recess 314 and a metal layer 213 formed at the bottom of the recess 315. In some embodiments, each of the metal layers 212 and 213 covers the remaining portions of the layers 154, 155, 156, 157 and 158. The metal layer 212 or 213 may or may not contact the spacers 152. In some embodiments, each of the metal layers 212 and 213 is in physical contact with the spacers 152 as shown in FIG. 17B. Similarly, the metal layer 212 or 213 may or may not contact the first work function layer 145. In some embodiments as shown in FIG. 17B, the metal layer 212 or 213 is in physical contact with the first work function layer 145.

In some embodiments, the metallic material 21 includes fluorine free tungsten (FFW) or other suitable conductive materials. In some embodiments, the metal layer 212 is electrically connected or in physical contact with the remaining portion of the metal layer 159. In some embodiments, the metal layer 213 is electrically connected or in physical contact with the remaining portion of the metal layer 159. In some embodiments, the remaining portions of the layers 144, 145, 146 and 147 and the metal layer 211 together define a gate electrode of a gate structure 14, and the spacers 142 are considered as a gate spacer of the gate structure 14. In some embodiments, the remaining portions of the layers 154, 155, 156, 157, 158 and 159 and the metal layers 212 and 213 together define a gate electrode of a gate structure 15, and the spacers 152 are considered as a gate spacer of the gate structure 15.

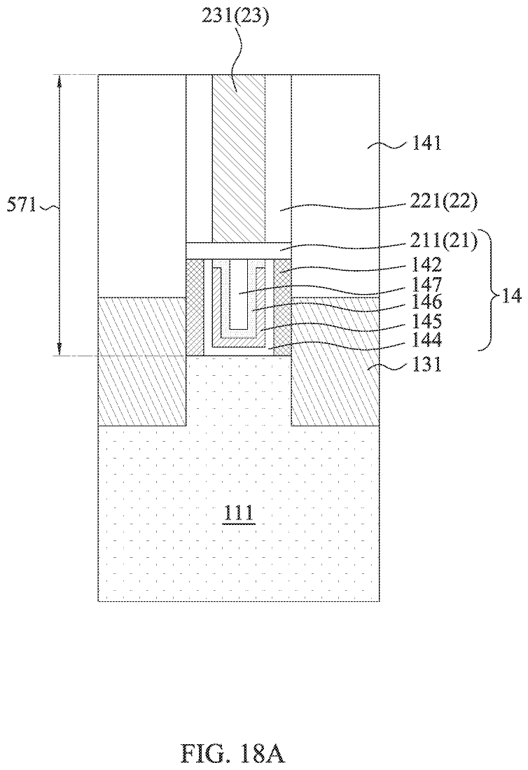

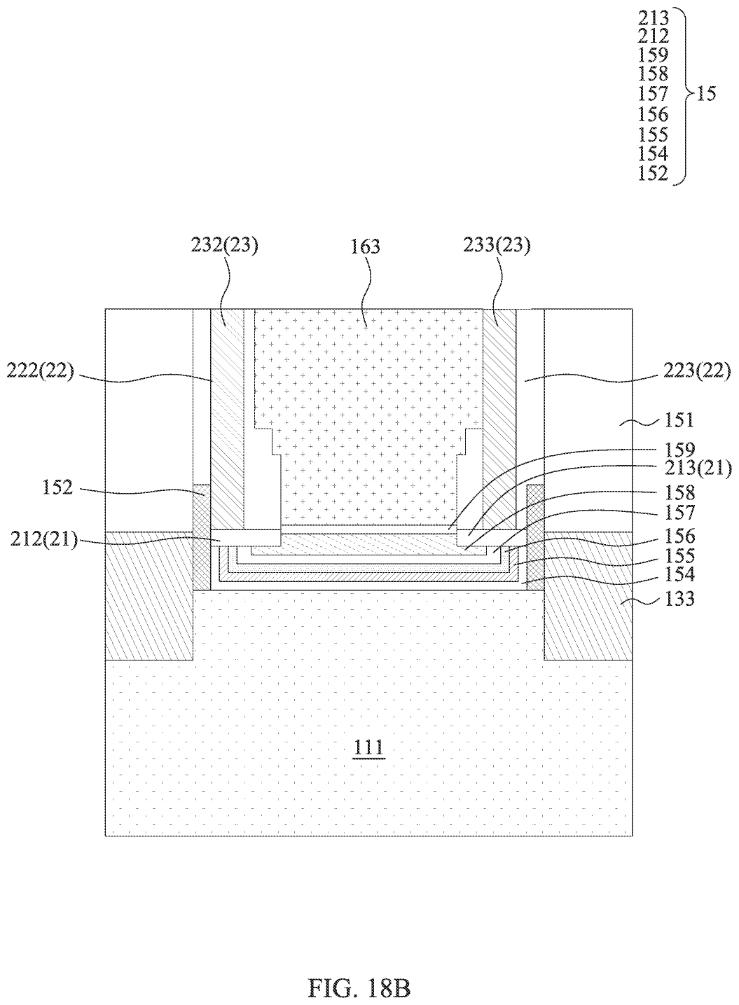

FIGS. 18A and 18B are schematic cross-sectional diagrams at a stage of the method 600 and/or the method 700 in accordance with some embodiments of the present disclosure. The method 600 and/or the method 700 may further include formation of a dielectric material 22 and a plurality of contact plugs 23. In some embodiments, a deposition of the dielectric material 22 is performed to fill the recesses 313, 314 and 315 shown in FIGS. 17A and 17B. An etch-back operation can be optionally performed after the deposition of the dielectric material 22 to remove portions of the dielectric material 22 above the dielectric layers 141 and 151. In some embodiments, the contact plugs 23 are formed after the formation of the dielectric material 22. In some embodiments, each of the contact plugs 23 penetrates the dielectric material 22. In some embodiments, the formation of the contact plugs 23 includes removal of portions of the dielectric material 22 to expose portions of the metallic material 21, and a deposition of conductive material is subsequently performed.

In some embodiments, a portion of the dielectric material 22 over the metal layer 211 becomes a dielectric layer 221, and a contact plug 231 penetrates the dielectric layer 221. The contact plug 231 is electrically connected to the metal layer 211. In some embodiments, a distance 571 between a top surface of the contact plug 231 and the fin structure 111 is in a range of 50 to 200 nm. In some embodiments, the distance 571 is in a range of 60 to 120 nm. In some embodiments, a portion of the dielectric material 22 over the metal layer 212 becomes a dielectric layer 222, and a contact plug 232 penetrates the dielectric layer 222. The contact plug 232 is electrically connected to the metal layer 212. In some embodiments, the contact plug 232 is disposed between the dielectric layers 163 and 151. In some embodiments, the contact plug 232 is disposed between the dielectric layers 163 and one of the source/drain structures 133. In some embodiments, a portion of the dielectric material 22 over the metal layer 213 become a dielectric layer 223, and a contact plug 233 penetrates the dielectric layer 223. The contact plug 233 is electrically connected to the metal layer 213. In some embodiments, the contact plug 233 is disposed between the dielectric layers 163 and 151. In some embodiments, the contact plug 233 is disposed between the dielectric layers 163 and one of the source/drain structures 133. The contact plugs 232 and 233 may be separated from the dielectric layer 163 or in contact with the dielectric layer 163 depending on widths of the recesses 314 and 315 shown in FIG. 17B. In some embodiments, the contact plug 232 is separated from the dielectric layer 163 by a portion of the dielectric layer 222. In some embodiments, the contact plug 233 is connected to the dielectric layer 163. In some embodiments in which the metal layers 212 and 213 are not electrically connected through the metal layer 159, the contact plugs 232 and 233 are electrically connected through metal lines of an interconnect structure (not shown) formed above the contact plugs 23 during subsequent processing.

In accordance with some embodiments of the disclosure, a method for manufacturing a semiconductor structure is provided. The method includes a number of operations. A substrate including a fin structure is received, provided or formed. A sacrificial gate layer is formed over the fin structure and a source/drain structure is formed adjacent to the sacrificial gate layer, wherein the sacrificial gate layer is surrounded by a dielectric structure. The sacrificial gate layer is removed, wherein a recess is defined by the dielectric structure. A work function layer is formed in the recess, wherein the work function layer includes an overhang portion at an opening of the recess. A thickness of the work function layer is reduced. A glue layer is formed over the work function layer.

In accordance with some embodiments of the disclosure, a method for manufacturing a semiconductor structure is provided. The method includes a number of operations. A substrate including a first sacrificial layer surrounded by a first isolation and a second sacrificial layer surrounded by a second isolation is received, provided or formed. The first sacrificial layer and the second sacrificial layer are removed, wherein a first recess is defined by the first isolation and a second recess is defined by the second isolation, and a width of the first recess is less than a width of the second recess. A first metal layer is formed in the first recess and the second recess, wherein the first metal layer includes an overhang portion at an opening of the first recess. A thickness of the first metal layer is reduced. A second metal layer filling the first recess and conformal to the second recess is formed.

In accordance with some embodiments of the disclosure, a semiconductor structure is provided. The semiconductor structure includes a fin structure; a first pair of source/drain structures and a second pair of source/drain structures disposed in the fin structure, wherein a first distance between the first pair of source/drain structures is less than a second distance between the second pair of source/drain structures; a first metal layer, disposed over the fin structure, between the first pair of source/drain structures, and between the second pair of source/drain structures; a second metal layer, disposed over the fin structure and between the second pair of source/drain structures, wherein the second metal layer is absent between the first pair of source/drain structures; a dielectric layer, disposed over the fin structure and between the second pair of source/drain structures; a first contact plug, disposed over the first metal layer and between the first pair of source/drain structures; and a second contact plug and a third contact plug, disposed over the first metal layer, wherein each of the second contact plug and the third contact plug is disposed between the dielectric layer and one of the second pair of source/drain structures.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of manufacturing a semiconductor structure, comprising:
receiving a substrate, including a fin structure;
forming a sacrificial gate layer over the fin structure and a source/drain structure adjacent to the sacrificial gate layer, wherein the sacrificial gate layer is surrounded by a dielectric structure;
removing the sacrificial gate layer, wherein a recess is defined by the dielectric structure;
forming a work function layer in the recess, wherein the work function layer includes an overhang portion at an opening of the recess;
reducing a thickness of the work function layer; and
forming a glue layer over the work function layer.

2. The method of claim 1, wherein the overhang portion of the work function layer is removed during the reduction of the thickness of the work function layer.

3. The method of claim 1, wherein the reduction of the thickness of the work function layer includes a dry etching operation.

4. The method of claim 1, wherein the thickness of the work function layer is reduced by 20% to 60%.

5. The method of claim 1, wherein the thickness of the work function layer prior to the reduction is in a range of 30 to 100 angstroms.

6. The method of claim 1, wherein the glue layer and the work function layer includes a same material.

7. The method of claim 1, further comprising:
removing a portion of the glue layer and a portion of the work function layer in the recess, wherein the removal stops above the fin structure by 5 to 30 nanometers.

8. A method of manufacturing a semiconductor structure, comprising:
receiving a substrate, including a first sacrificial layer surrounded by a first isolation and a second sacrificial layer surrounded by a second isolation;
removing the first sacrificial layer and the second sacrificial layer, wherein a first recess is defined by the first isolation, a second recess is defined by the second isolation, and a width of the first recess is less than a width of the second recess;
forming a first metal layer in the first recess and the second recess, wherein the first metal layer includes an overhang portion at an opening of the first recess;
reducing a thickness of the first metal layer; and
forming a second metal layer filling the first recess and conformal to the second recess.

9. The method of claim 8, further comprising:
forming a third metal layer over the second metal layer, wherein the third metal layer is disposed over the first recess and in the second recess.

10. The method of claim 8, further comprising:
forming a first dielectric layer over the second metal layer in the second recess; and
removing portions of the first metal layer and the second metal layer between the dielectric layer and the second isolation in the second recess, and portions of the first metal layer and the second metal layer in the first recess.

11. The method of claim 10, further comprising:
forming a fourth metal layer covering tops of remaining portions of the first metal layer and the second metal layer;
forming a second dielectric layer over the fourth metal layer; and
forming contact plugs penetrating the second dielectric layer and electrically connected to the remaining portions of the first metal layer and the second metal layer.

12. The method of claim 10, wherein an entirety of the second metal layer in the first recess is removed, and a portion of the second metal layer disposed on a bottom of the second recess is left remaining after the removal of the portions of the first metal layer and the second metal layer.

13. The method of claim 8, wherein the reduction of the thickness of the first metal layer includes a dry etch, and a removal rate of the dry etch on a horizontal portion of the first metal layer is greater than a removal rate of the dry etch on a vertical portion of the first metal layer.

14. The method of claim 8, further comprising:
forming an oxide layer over the first metal layer prior to the forming of the second metal layer.

15. The method of claim 14, wherein a thickness of the oxide layer is in a range of 0.5 to 2 nanometers.

16. The method of claim 8, wherein the width of the first recess is in a range of 20 to 100 nanometers, and the width of the second recess is in a range of 100 to 250 nanometers.

17. A semiconductor structure, comprising:
a fin structure;
a first pair of source/drain structures and a second pair of source/drain structures disposed in the fin structure, wherein a first distance between the first pair of source/drain structures is less than a second distance between the second pair of source/drain structures;
a first metal layer, disposed over the fin structure, between the first pair of source/drain structures, and between the second pair of source/drain structures;
a second metal layer, disposed over the fin structure and between the second pair of source/drain structures, wherein the second metal layer is absent between the first pair of source/drain structures;
a dielectric layer, disposed over the fin structure and between the second pair of source/drain structures;
a first contact plug, disposed over the first metal layer and between the first pair of source/drain structures; and
a second contact plug and a third contact plug, disposed over the first metal layer, wherein each of the second contact plug and the third contact plug is disposed between the dielectric layer and one of the second pair of source/drain structures.

18. The semiconductor structure of claim 17, further comprising:
an oxide layer, disposed between the first metal layer and the second metal layer, wherein the oxide layer is absent between the first pair of source/drain structures.

19. The semiconductor structure of claim 17, wherein a first thickness of the first metal layer between the first pair of source/drain structures is greater than a second thickness of the first metal layer between the second pair of source/drain structures.

20. The semiconductor structure of claim 17, wherein a distance between the second contact plug and a top of the dielectric layer is less than a distance between the second contact plug and a bottom of the dielectric layer.
